(19) United States
(12) Patent Application Publication
(10) Pub. No.: US 2025/0374644 A1
(43) Pub. Date: Dec. 4, 2025

(54) APPARATUS INCLUDING MEMORY CELL CAPACITOR AND CELL CONTACT

(71) Applicant: MICRON TECHNOLOGY, INC., BOISE, ID (US)

(72) Inventors: Kunihiro Tsubomi, Hiroshima (JP); Manabu Ito, Hiroshima (JP)

(73) Assignee: MICRON TECHNOLOGY, INC., BOISE, ID (US)

(21) Appl. No.: 19/214,868

(22) Filed: May 21, 2025

Related U.S. Application Data
(60) Provisional application No. 63/655,406, filed on Jun. 3, 2024.

(51) Int. Cl. H10D 64/66; H10B 12/00

(52) U.S. Cl. CPC H10D 64/665; H10B 12/315; H10B 12/482; H10D 64/664

(57) ABSTRACT

Some embodiments of the disclosure provide an apparatus comprising a cell contact coupled to a memory cell capacitor. The cell contact includes a contact metal and a barrier film at least on a side surface of the contact metal. A lower portion of the barrier film comprises a barrier metal. An upper portion of the barrier film comprises an insulating film.

### CROSS-REFERENCE TO RELATED APPLICATIONS

This application claims the filing benefit of U.S. Provisional Application No. 63/655,406, filed Jun. 3, 2024. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). A semiconductor memory device may include a plurality of memory cells at intersections of word lines and bit lines. Each memory cell may include a memory cell capacitor to store data.

### BRIEF DESCRIPTION OF THE DRAWINGS

FIG. 1A depicts an example configuration of at least part of a semiconductor device in a plan view according to an embodiment of the disclosure.

FIG. 1B depicts an example configuration of at least part of a semiconductor device in a cross-sectional view according to an embodiment of the disclosure.

FIGS. 2A-8A depict example processes of manufacturing an example configuration of at least part of a semiconductor device in a plan view according to an embodiment of the disclosure.

FIGS. 2B-8B depict example processes of manufacturing an example configuration of at least part of a semiconductor device in a cross-sectional view according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

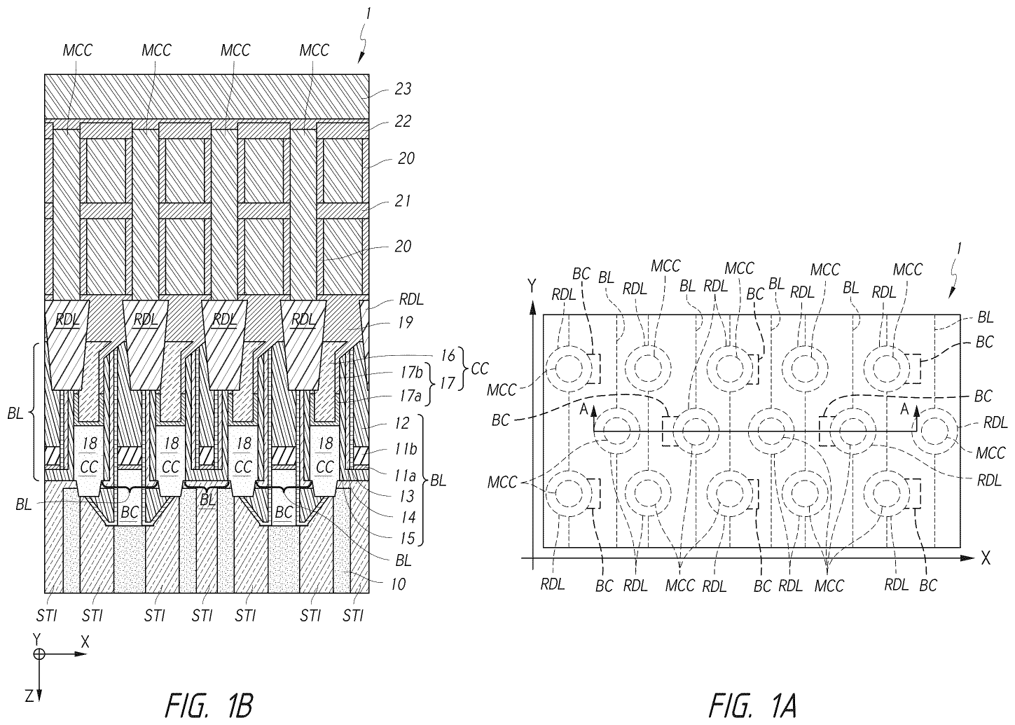

FIG. 1A depicts an example configuration of at least part of a semiconductor device 1 in a plan view according to an embodiment of the disclosure. FIG. 1B depicts an example configuration of at least part of the semiconductor device 1 in a cross-sectional view according to an embodiment of the disclosure. The cross-sectional view of FIG. 1B corresponds to an A-A line in FIG. 1A. The semiconductor device 1 may be a dynamic random-access memory (DRAM). The semiconductor device 1 may be one example of an apparatus. The semiconductor device 1 includes a plurality of memory cell capacitors MCC in a memory cell array region on a semiconductor substrate 10. The memory cell capacitors MCC may include a conductive material, such as titanium nitride (TiN). Adjacent to the memory cell capacitors MCC are high-k films 20. The high-k films 20 may include a high-k dielectric material, such as zirconium dioxide (ZrO₂). The example structure may also include insulating layers 21 and 22. The Insulating layers 21 and 22 may include an insulating material, such as silicon nitride (SiN). There may also be another conductive layer 23, including a conductive material, such as TiN.

The memory cell capacitors MCC are arranged at intersections of word lines (not separately depicted) and bit lines BL. Each memory cell capacitor MCC may form at least part of a memory cell to store data by accumulating electric charges therein and to be accessed via the associated word line and bit line during data write and read operations. Each memory cell MCC may include a vertical capacitor structure that extends in a vertical direction (for example, a Z-axis direction in the drawing). The word lines may be arranged in parallel with each other in one horizontal direction (for example, a Y-axis direction in the drawing) and each may extend in another horizontal direction (for example, an X-axis direction perpendicular to the Y-axis direction in the drawing). The bit lines BL may be arranged in parallel with each other in the X-axis direction and each may extend in the Y-axis direction.

Each bit line BL may include a bit line structure, which may include a first conductive part 11a and a second conductive part 11b on the first conductive part 11a. The first conductive part 11a as a lower conductive part may include a conductive material, such as TiN. The second conductive part 11b as an upper conductive part may include a conductive material, such as tungsten (W). On the second conductive part 11b is an insulating layer 12 including an insulating material, such as SiN. The first conductive part 11a, the second conductive part 11b, and the insulating layer 12 may be part of the bit line (or the bit line structure) BL. An oxidation prevention film 13 may be provided on side surfaces of the first and second conductive parts 11a and 11b and on a side surface of the insulating layer 12. The oxidation prevention film 13 may be a low-k film including a low-k dielectric material, such as silicon oxycarbide (SiOC) and silicon oxycarbonitride (SiOCN). Furthermore, an insulating film 14 may be provided on the oxidation prevention film 13. The insulating film 14 may include an insulating material, such as silicon dioxide (SiO₂). Still furthermore, another insulating film 15 may be provided on the insulating film 14. The insulating film 15 may include an insulating material, such as SiN, different from the insulating material of the insulating film 14. The oxidation prevention film 13, the insulating film 14, and the insulating film 15 may also be part of the bit line (or the bit line structure) BL.

The bit lines BL may be coupled to bit line contacts BC at lower ends. Each bit line contact BC may be coupled to a source region or a drain region formed in the semiconductor substrate 10. The semiconductor device 1 may also include shallow trench isolations STI provided in the semiconductor substrate 10. The shallow trench isolations STI may include an insulating material, such as SiO₂.

The semiconductor device 1 may include redistribution layers RDL coupled to the memory cell capacitors MCC and cell contacts CC at upper ends and lower ends, respectively. The redistribution layers RDL couple the memory cell capacitors MCC to the cell contacts CC. Each redistribution layer RDL may include a conductive material, such as W.

Each cell contact CC may include a cell contact structure, which may include a first contact part 16 and a second contact part 17 at least on a side surface the first contact part 16. The first contact part 16 extends in the Z-axis direction and may include a conductive material, such as W. The first contact part may also be referred to as a contact metal.

The second contact part 17 may include a barrier metal 17a as a lower portion thereof and an insulating film 17b as an upper portion thereof. The barrier metal 17a is in a film form on a lower portion of the side surface of the first contact part (or the contact metal) 16 and on a bottom surface of the first contact part 16. The barrier metal 17a may also be referred to as a barrier metal film. The barrier metal 17a may include a conductive material, such as TiN, different from the conductive material of the first contact part 16. The insulating film 17b is on an upper portion of the side surface of the first contact part 16. The insulating film may include an insulating material, such as SiN. The barrier metal 17a and the insulating film 17b together may form a barrier film at least on the side surface of the first contact part 16. The second contact part 17 may thus be referred to as the barrier film. The barrier metal 17a may be a lower portion of the barrier film, and the insulating film 17b may be an upper portion of the barrier film.

In one instance, the second contact part (or the barrier film) 17 may be formed in a contact hole (not separately depicted in FIGS. 1A and 1B), and the first contact part (or the contact metal) 16 may be formed on the second contact part 17 filling the contact hole. Under the first and second contact parts 16 and 17 is a third contact part 18 extending into the semiconductor substrate 10 in the Z-axis direction. The third contact part 18 may include a conductive material, such as a polycrystalline silicon or polysilicon, different from the conductive materials of the first and second contact parts 16 and 17. The third contact part 18 may be coupled to a source region or a drain region formed in the semiconductor substrate 10. The third contact part 18 together with the first and second contact parts 16 and 17 may be part of the cell contact (or the cell contact structure) CC.

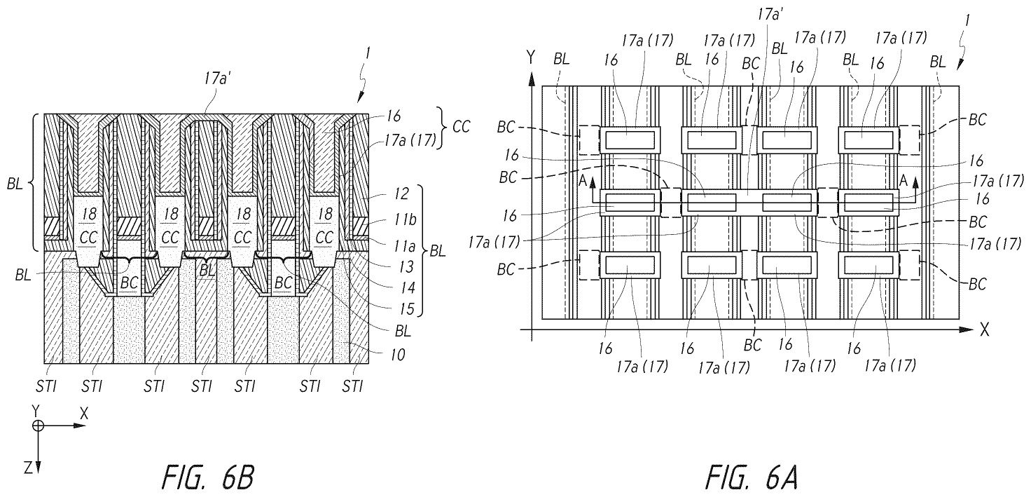

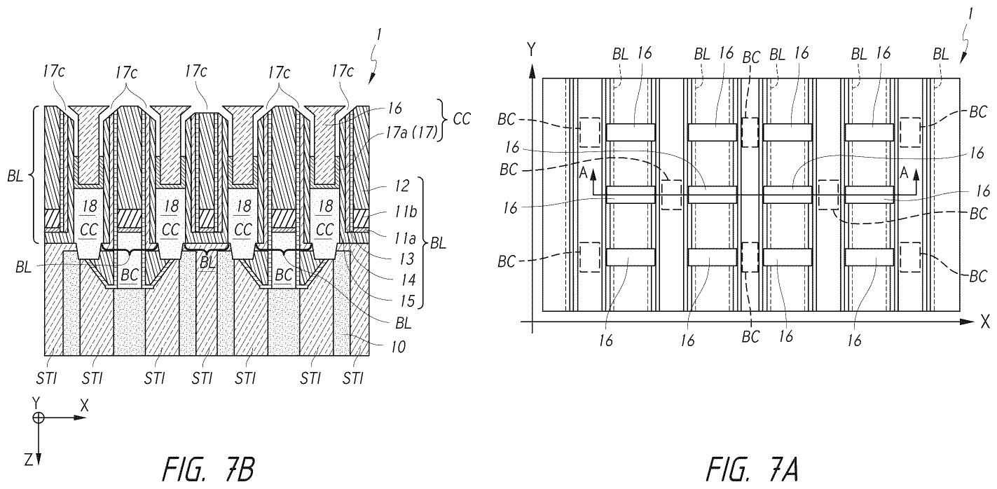

In the example configuration, a top portion of the barrier metal 17a of the second contact part 17 is lower than a top portion of the first contact part 16. A space or an opening (see, for example, 17c in FIG. 7B) between the top portion of the barrier metal 17a and the top portion of the first contact part 16 is filled with an insulating material, such as SiN, to form the insulating film 17b of the second contact part 17. The insulating material may be part of an insulating layer 19 that covers the top portion of each cell contact CC and fills spaces between the neighboring redistribution layers RDL. In one instance, the barrier metal 17a in the film form may be first provided in the contact hole and then may be selectively wet-etched to make the top portion thereof lower than the top portion of the first contact part 16 before the insulating film 17b is provided in the space/opening created by the wet etching on the remaining part of the barrier metal 17a. Unlike a case where the top portion of the second contact part 17 remains on the top portion of the bit line structure BL and forms a conductive bridge between the neighboring cell contact structures CC adjacent to the bit line structure BL (see, for example, 16b′ in FIGS. 6A and 6B which will be described in detail below), in the example configuration according to the present embodiment where the second contact part (or the barrier film) 17 includes the barrier metal 17a as the lower portion thereof and the insulating film 17b as the upper portion thereof at least on the side surface of the first contact part 16, the top portion of the barrier metal 17a is lower than the top portion of first contact part 16 and hence does not form a conductive bridge on the top portion of the bit line structure BL. Consequently, a short circuit can be effectively avoided between the neighboring cell contact structures CC.

Furthermore, the top portion of the barrier metal 17a may be lower than a top portion of the bit line structure BL. For example, the top portion of the barrier metal 17a may be lower than at least a top portion of the insulating layer 12 of the bit line structure BL. This may further ensure that the neighboring cell circuit structures CC are not short circuited with each other.

Still furthermore, the top portion of the barrier metal 17a may be lower than a bottom portion of the redistribution layer RDL. This way, a short circuit may be further effectively avoided between the barrier metal 17a and the redistribution layer RDL which may be coupled only to the first contact part 16.

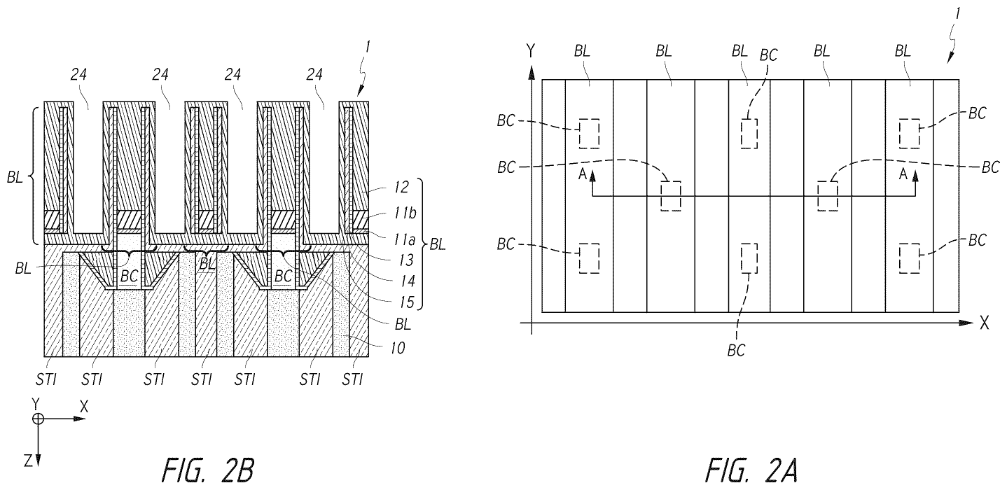

FIGS. 2A-8A depict example processes of manufacturing an example configuration of at least part of the semiconductor device 1 in a plan view according to an embodiment of the disclosure. FIGS. 2B-8B depict example processes of manufacturing an example configuration of at least part of the semiconductor device 1 in a cross-sectional view according to an embodiment of the disclosure.

First, as shown in FIGS. 2A and 2B, a part of the semiconductor device 1 is formed, including, for example, the shallow trench isolations STI and the bit line contacts BC in the semiconductor substrate 10 and the bit line structures BL on the semiconductor substrate 10 Between the neighboring bit line structures BL are cell contact holes 24.

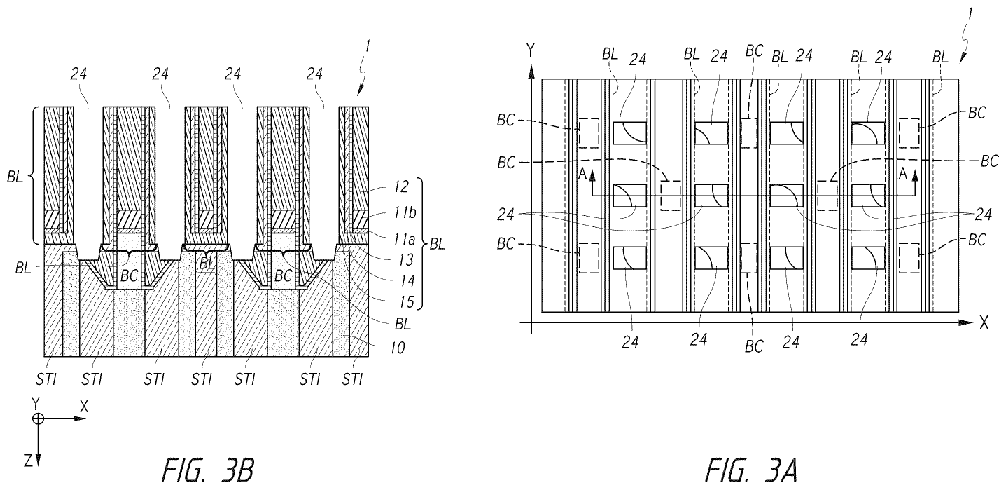

Next, as shown in FIGS. 3A and 3B, the cell contact holes 24 are vertically patterned to extend into the semiconductor substrate 10 by, for example, etching. A top portion of each bit line structure BL may also be etched.

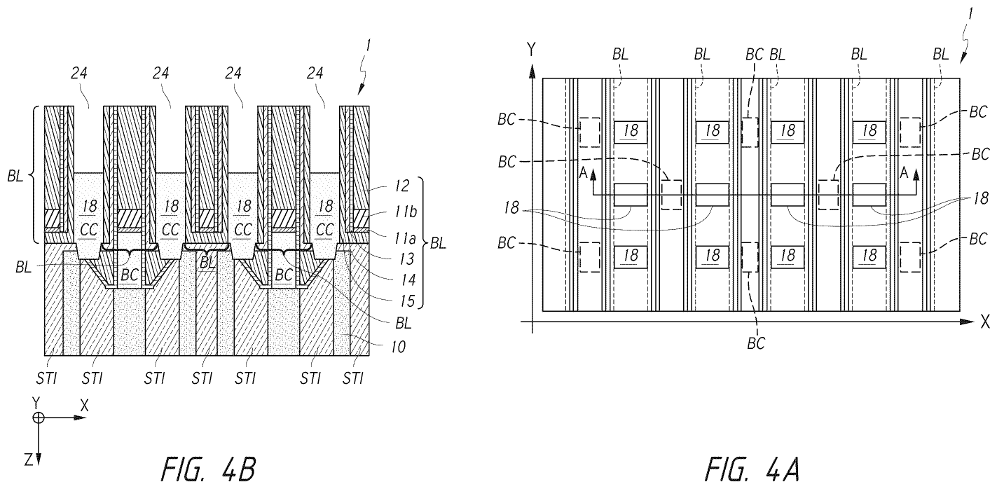

Next, as shown in FIGS. 4A and 4B, the third contact part 18 as part of the cell contact structure CC is provided in each cell contact hole 24. Dry etching may be applied after the third contact part 18 is buried in the cell contact hole 24.

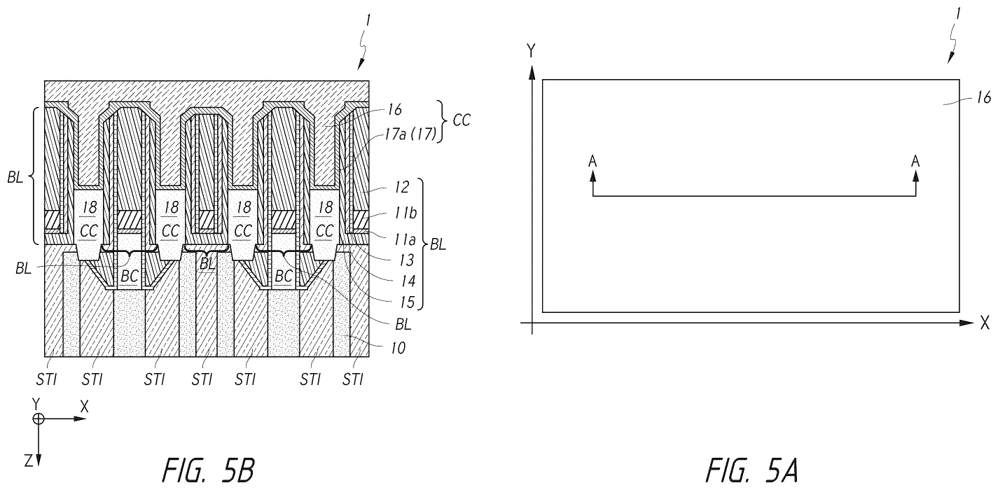

Next, as shown in FIGS. 5A and 5B, the first contact part 16 and the second contact part 17 as part of the cell contact structure CC are provided on the third contact part 18 in each cell contact hole 24 (FIG. 4B). For example, the barrier metal 17a as part of the second contact part 17 is formed on a top surface of the third contact part 18 and a side surface of the cell contact hole 24 as well as on the top portion of the bit line structure BL. The first contact part 16 is then provided on the barrier metal 17a and the top portion of the bit line structure BL. The first contact part 16 covers the barrier metal 17a and fills the cell contact hole 24.

Next, as shown in FIGS. 6A and 6B, to separate the cell contact structures CC from each other, a top portion of the barrier metal 17a on the top portion of the bit line structure BL and the first contact part 16 above the bit line structure BL are removed by, for example, chemical-mechanical polishing CMP or dry etching. In some instances, however, the top portion of the barrier metal 17a may remain on the top portion of the bit line structure BL due to fluctuation in depth of the top removal or due to fluctuation in height of the bit line structure BL. In FIG. 6B, the top portion 17a′ of one of the barrier metals 17a is left on the top portion of one of the bit line structures BL whose height in the Z-axis direction on the semiconductor substrate 10 is lower than the other bit line structures BL. This top portion 17a′ may form a conductive bridge between the neighboring cell contact structures CC and may cause a short circuit.

To effectively avoid such a short circuit, as shown in FIGS. 7A and 7B, a part of the barrier metal 17a of the second contact part 17 of each cell contact structure CC is selectively removed by, for example, wet etching. The selective wet etching may use a liquid chemical or an etchant, such as sulfuric acid. The etch rate may be determined to be greater for the conductive material, such as TiN, of the barrier metal 17a than for the conductive material, such as W, of the first contact part 16 so that the part of the barrier metal 17a is etched within a predetermined period of time while the first contact part 16 is not etched or not substantially etched. Furthermore, the etch rate for the conductive material of the barrier metal 17a may be greater than that for the insulating material, such as SiN, of the insulating layer 12 of the bit line structure BL. The wet etching thus etches the part of the barrier metal 17a but does not etch or does not substantially etch the insulating layer 12 of the bit line structure BL. By adjusting conditions of the wet etching including etchant, etch rate, etch time, temperature, and the like, the top portion of the barrier metal 17a is selectively etched to be lower than the top portion of the first contact part 16. The top portion of the barrier metal 17a also becomes lower than the top portion of the bit line structure BL. This removal of the top portion of the barrier metal 17a of the second contact part 17 forms a space or an opening 17c between the remaining top portion of the second contact part 17 and the top portion of the first contact part 16. This way, in comparison with the case where the top portion 17a′ (FIG. 6B) remains as a conductive bridge on the top portion of the bit line structure BL, a short circuit between the neighboring cell contact structures CC is effectively prevented.

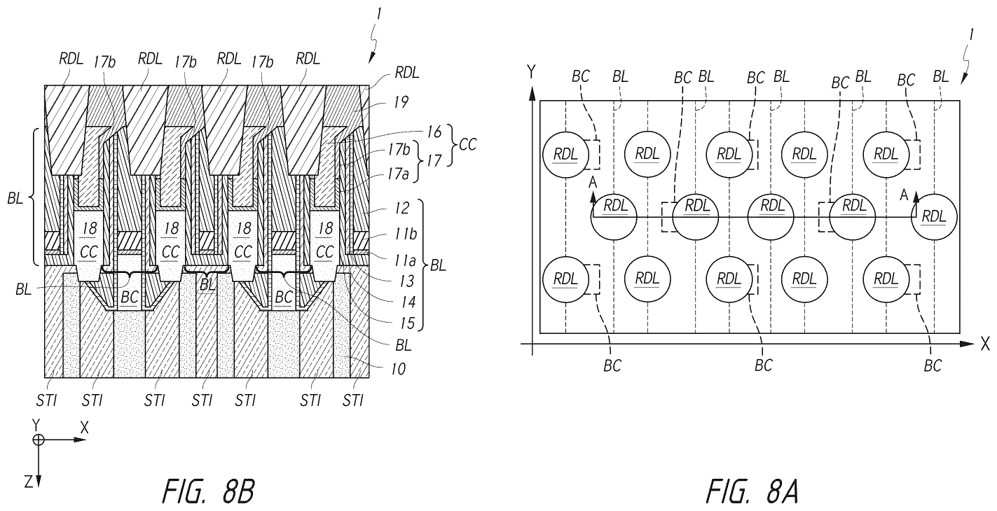

Subsequently, as shown in FIGS. 8A and 8B, the redistribution layer RDL and the insulating layer 19 are provided on the cell contact structures CC and the bit line structure BL. The insulating material of the insulating layer 19 fills the space/opening 17c (FIG. 7B) and forms the insulating film 17b on the side surface of the first contact part 16. The top portion of the barrier metal 17a may also become lower than the bottom portion of the redistribution layer RDL. Although not depicted in FIGS. 8A and 8B, in some instances, not all of the barrier metals 17a may have their top portions lower than the bottom portions of the corresponding redistribution layers RDL. For example, only some of the barrier metals 17a may have their top portions lower than the bottom portions of corresponding ones of the redistribution layers RDL.

Following the above process, as shown in FIGS. 1A and 1B, the memory cell capacitors MCC are formed on the corresponding redistribution layers RDL.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising a cell contact coupled to a memory cell capacitor, the cell contact including a contact metal and a barrier film at least on a side surface of the contact metal, wherein
a lower portion of the barrier film comprises a barrier metal; and
an upper portion of the barrier film comprises an insulating film.

2. The apparatus according to claim 1, wherein a top portion of the barrier metal of the barrier film is lower than a top portion of the contact metal.

3. The apparatus according to claim 1, wherein the insulating film of the barrier film includes silicon nitride.

4. The apparatus according to claim 3, wherein the contact metal includes tungsten, and the barrier metal of the barrier film includes titanium nitride.

5. The apparatus according to claim 1, wherein
the contact metal extends in a vertical direction on a semiconductor substrate, the insulating film of the barrier film is on an upper portion of the side surface of the contact metal, and the barrier metal of the barrier film is on a lower portion of the side surface of the contact metal and on a bottom surface of the contact metal, and
the cell contact further includes a part under the contact metal and the barrier film, the part extending in the vertical direction into the semiconductor substrate.

6. The apparatus according to claim 5, wherein the contact metal includes tungsten, the insulating film of the barrier film includes silicon nitride, the barrier metal of the barrier film includes titanium nitride, and the part includes polycrystalline silicon.

7. The apparatus according to claim 1, further comprising a bit line structure, wherein a top portion of the barrier metal of the barrier film is lower than a top portion of the bit line structure.

8. The apparatus according to claim 1, further comprising a redistribution layer (RDL) configured to couple the cell contact to the memory cell capacitor, wherein a top portion of the barrier metal of the barrier film is lower than a bottom portion of the RDL.

9. The apparatus according to claim 1, further comprising:
a bit line structure; and
a redistribution layer (RDL) configured to couple the cell contact to the memory cell capacitor, wherein
a top portion of the barrier metal of the barrier film is lower than a top portion of the bit line structure and lower than a bottom portion of the RDL.

10. An apparatus, comprising:
a cell contact coupled to a memory cell capacitor, the cell contact including a contact metal and a barrier film at least on a side surface of the contact metal; and
a bit line structure, wherein
a lower portion of the barrier film comprises a barrier metal,
an upper portion of the barrier film comprises an insulating film, and
a top portion of the barrier metal of the barrier film is lower than a top portion of the contact metal and lower than a top portion of the bit line structure.

11. The apparatus according to claim 10, wherein
the contact metal extends in a vertical direction on a semiconductor substrate, the insulating film of the barrier film is on an upper portion of the side surface of the contact metal, and the barrier metal of the barrier film is on a lower portion of the side surface of the contact metal and on a bottom surface of the contact metal, and
the cell contact further includes a part under the contact metal and the barrier film, the part extending in the vertical direction into the semiconductor substrate.

12. The apparatus according to claim 11, wherein the contact metal includes tungsten, the insulating film of the barrier film includes silicon nitride, the barrier metal of the barrier film includes titanium nitride, and the part includes polycrystalline silicon.

13. The apparatus according to claim 10, further comprising a redistribution layer (RDL) configured to couple the cell contact to the memory cell capacitor, wherein the top portion of the barrier metal of the barrier film is lower than a bottom portion of the RDL.

14. An apparatus, comprising a cell contact coupled to a memory cell capacitor, the cell contact including a first contact part and a second contact part on at least a side surface of the first contact part, wherein
the second contact part includes:
a barrier metal film on a lower portion of the side surface of the first contact part; and
an insulating film on an upper portion of the side surface of the first contact part.

15. The apparatus according to claim 14, wherein a top portion of the barrier metal film of the second contact part is lower than a top portion of the first contact part.

16. The apparatus according to claim 14, wherein the first contact part includes tungsten, the barrier metal film of the second contact part includes titanium nitride, and the insulating film of the second contact part includes silicon nitride.

17. The apparatus according to claim 14, wherein
the cell contact further includes a third contact part under the first and second contact parts, and
the first contact part includes tungsten, the barrier metal film of the second contact part includes titanium nitride, the insulating film of the second contact part includes silicon nitride, and the third contact part includes polycrystalline silicon.

18. The apparatus according to claim 14, further comprising a bit line structure, wherein a top portion of the barrier metal film of the second contact part is lower than a top portion of the bit line structure.

19. The apparatus according to claim 14, further comprising a redistribution layer (RDL) configured to couple the cell contact to the memory cell capacitor, wherein a top portion of the barrier metal film of the second contact part is lower than a bottom portion of the RDL.

20. The apparatus according to claim 14, further comprising:
a bit line structure; and
a redistribution layer (RDL) configured to couple the cell contact to the memory cell capacitor, wherein
a top portion of the barrier metal film of the second contact part is lower than a top portion of the bit line structure and lower than a bottom portion of the RDL.
